(19) United States
(12) Patent Application Publication
(10) Pub. No.: US 2026/0026072 A1
(43) Pub. Date: Jan. 22, 2026

(54) SEMICONDUCTOR DEVICES WITH ASYMMETRIC INSULATING LAYERS AND METHODS OF FABRICATION THEREOF

(71) Applicant: TEXAS INSTRUMENTS INCORPORATED, Dallas, TX (US)

(72) Inventors: Robert Cassel, Lehi, UT (US); Alexei Sadovnikov, Sunnyvale, CA (US); Jackson Bauer, Rowlett, TX (US); Joseph M. Khayat, Bedford, NH (US)

(21) Appl. No.: 18/774,279

(22) Filed: Jul. 16, 2024

(51) Int. Cl. H01L 29/423; H01L 21/02; H01L 21/28; H01L 29/40; H01L 29/78

(52) U.S. Cl. CPC H10D 64/516; H01L 21/0234; H01L 21/02345; H01L 21/28158; H10D 30/65; H10D 64/01

(57) ABSTRACT

Semiconductor devices and fabrication methods thereof are described. For example, a semiconductor device includes a semiconductor layer, a source region disposed in the semiconductor layer, a drain region disposed in the semiconductor layer, a gate electrode, and an insulating layer disposed between a portion of the gate electrode and the semiconductor layer. The insulating layer has a first sidewall extending toward the source region and a second sidewall extending toward the drain region, the first sidewall having a first slope and the second sidewall having a second slope greater than the first slope.

### TECHNICAL FIELD

The present disclosure relates to the field of semiconductor transistors, and more particularly, but not exclusively, to laterally diffused metal oxide semiconductor (LDMOS) transistors.

### BACKGROUND

LDMOS devices are field-effect transistors (FETs) designed for high power applications. In an LDMOS device, the drain and source have a relatively large spacing between them, as compared with MOS devices designed for other applications, and lateral diffusions are used to produce a well-controlled carrier drift region under the gate. The operational performance of LDMOS devices is generally affected by parameters including, for example, a specific on-resistance (Rsp) and a breakdown voltage (BV). One design goal of LDMOS devices is to decrease Rsp and increase BV, or at least to improve one parameter without adversely affecting the other parameter.

### SUMMARY

The present disclosure describes semiconductor devices with asymmetric insulating layers and methods of fabrication thereof. This summary is not an extensive overview of the disclosure. Rather, a purpose of the summary is to present some examples of the present disclosure in a simplified form as a prelude to a more detailed description that is presented later.

In some examples, a semiconductor device includes a semiconductor layer, a source region disposed in the semiconductor layer, a drain region disposed in the semiconductor layer, a gate electrode, and an insulating layer disposed between a portion of the gate electrode and the semiconductor layer. The insulating layer has a first sidewall extending toward the source region and a second sidewall extending toward the drain region, the first sidewall having a first slope and the second sidewall having a second slope greater than the first slope.

In some other examples, a semiconductor device includes a semiconductor layer, a source region disposed in the semiconductor layer, a drain region disposed in the semiconductor layer, a gate electrode, and an asymmetric graded field dielectric layer disposed between a portion of the gate electrode and the semiconductor layer. The asymmetric graded field dielectric layer has a first sloped section extending toward the source region and a second sloped section extending toward the drain region.

In some additional examples, a method of fabricating a semiconductor device includes forming an insulating layer over a semiconductor layer, the insulating layer having a first sidewall extending toward a first side and a second sidewall extending toward a second side opposite the first side, the first sidewall having a first slope and the second sidewall having a second slope greater than the first slope, forming a gate electrode over at least a portion of the insulating layer, forming a source region in the semiconductor layer, the source region spaced apart from the first side by the semiconductor layer, and forming a drain region in the semiconductor layer, the drain region proximate to the second side.

### BRIEF DESCRIPTION OF THE DRAWINGS

FIGS. 1A and 1B are cross-sectional views of semiconductor devices with asymmetric insulating layers in accordance with examples of the present disclosure;

FIG. 2 is a cross-sectional view of asymmetric insulating layer scaling for different voltage characteristics of semiconductor devices in accordance with examples of the present disclosure;

FIG. 3 is a cross-sectional view of asymmetric insulating layer with multiple slopes in accordance with examples of the present disclosure;

FIGS. 4A-4L are cross-sectional views of a first process flow for forming asymmetric insulating layers of semiconductor devices in accordance with examples of the present disclosure; and

FIGS. 5A-5D are cross-sectional views of a second process flow for forming an asymmetric insulating layer of a semiconductor device in accordance with examples of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean +/−10-20 percent of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, the operational performance of an LDMOS device is generally affected by a tradeoff between a specific on-resistance (Rsp) parameter and a breakdown voltage (BV) parameter. For example, design approaches that seek to achieve the advantage of a higher BV by increasing the body area of the device consequently lead to the disadvantage of a higher Rsp. Similarly, design approaches that seek to decrease Rsp generally come at the cost of decreasing the BV rating. Accordingly, LDMOS design approaches that effectively manage this tradeoff provide technical advantages.

LDMOS and other power devices may utilize field relief dielectrics for tuning the Rsp and BV parameters. Approaches for field relief dielectrics for LDMOS and other power devices including local oxidation of silicon (LOCOS), shallow trench isolation (STI), and abrupt or sharp-edge step gate approaches. The LOCOS approach forms a field relief dielectric with a bird's beak with tapered corners near a hard mask edge leading to a weak point for breakdown and hot carriers. The bird's beak benefits the field relief at the expense of increased Rsp. Further, the symmetric nature of LOCOS leaves a thin field oxide on the drain side. While the LOCOS approach provides some depth scaling, due to aspect ratio impacts, the depth scaling is controllable only over a limited range of LOCOS critical dimensions. The STI and step gate approaches result in sharp corners, which create weak points for breakdown and hot carriers.

Semiconductor devices, such as LDMOS devices, are described herein which allow for improved Rsp while reducing device area. In some examples, this and other technical advantages may be achieved through introduction of an insulating layer (also referred to as a field relief dielectric) that has a smooth, shallow slope on the side that extends toward the source, and a steeper slope on the side that is away from the source. In examples, the insulating layer may have a tapered smooth rise from the source side toward the drain side, and then a steep slope from a maximum thickness toward the drain side. Thus, the insulating layer is asymmetric and may be referred to, in at least some examples, as an asymmetric insulating layer, an asymmetric dielectric layer, etc. The asymmetric insulating layer has an adjustable thickness, as well as an adjustable slope and lateral scaling characteristics, such that relatively low voltage (LV) and relatively high voltage (HV) LDMOS devices can be formed in different regions of a wafer or other structure. The sloped profile of the asymmetric insulating layer leads to improved Rsp, while also providing reduced device area due to the asymmetric shape.

In some examples, a semiconductor device includes a semiconductor layer, a source region disposed in the semiconductor layer, a drain region disposed in the semiconductor layer, a gate electrode, and an asymmetric insulating layer (e.g., a dielectric layer, a field relief layer, a field relief dielectric, etc.) disposed between a portion of the gate electrode and the semiconductor layer, the asymmetric insulating layer having a first sidewall extending toward the source region (and thereby, e.g., the channel) and a second sidewall extending toward the drain region. The first sidewall has a first slope and the second sidewall has a second slope greater than the first slope. The asymmetric insulating layer may include a dielectric material selected to provide field relief. The asymmetric insulating layer may be formed of an oxide material, a nitride material, combinations thereof, etc. The first slope of the first sidewall may be a composite of two or more component slopes, where the two or more component slopes include a first component slope proximate the source region and at least a second component slope proximate the drain region, where the first component slope is less than the second component slope. At least a portion of the gate electrode may extend past an edge of the asymmetric insulating layer towards the source region. At least a portion of the asymmetric insulating layer may extend past an edge of the gate electrode towards the drain region. The first sidewall of the asymmetric insulating layer may have a first length, and the second sidewall of the asymmetric insulating layer may have a second length that is less than the first length. The asymmetric insulating layer may include a non-sloped portion (e.g., a horizontal or flat portion, with a slope of at or about zero degrees) that extends between the first sidewall and the second sidewall.

The first sidewall may include a first portion with the first slope and a second portion with a third slope less than the second slope. The first sidewall may include two or more component slopes including a first component slope between the source region and the drain region and at least a second component slope between the first component slope and the drain region, the first component slope being less than the second component slope. The first sidewall of the insulating layer may include a scalloped contour.

The asymmetric insulating layer may include a dielectric layer (or region) configured to provide field relief, and may be referred to as an asymmetric dielectric layer, a graded dielectric layer, or an asymmetric graded dielectric layer. The asymmetric graded dielectric layer has a first sloped section (e.g., a shallow-sloped section) that extends toward the source region and a second sloped section (e.g., a steep-sloped section) that extends toward the drain region. The first sloped section of the asymmetric graded dielectric layer may have a first width, and the second sloped section of the asymmetric graded dielectric layer may have a second width less than the first width. The asymmetric graded dielectric layer may include a non-sloped section (e.g., a horizontal or flat portion, with a slope of at or about zero degrees) between the first sloped section and the second sloped section. A first slope of the first sloped section of the asymmetric graded dielectric layer is different than a second slope of the second sloped section of the asymmetric graded dielectric layer, where the second slope is greater than the first slope.

Methods for fabricating semiconductor devices, such as LDMOS devices, include forming an asymmetric insulating layer over a semiconductor layer, where the asymmetric insulating layer has a first sidewall extending toward a first side and a second sidewall extending toward a second side opposite the first side, the first sidewall having a first slope and the second sidewall having a second slope greater than the first slope. The methods also include forming a gate electrode over at least a portion of the asymmetric insulating layer, forming a source region in the semiconductor layer, the source region proximate to the first side, and forming a drain region in the semiconductor layer, the drain region proximate to the second side.

Forming the asymmetric insulating layer may include forming an insulating material for the insulating layer over the semiconductor layer, forming a hard mask layer over the insulating material, forming a first patterning layer over a portion of the hard mask layer covering the drain region, performing a partial etch of an exposed portion of the hard mask layer, performing two or more iterations of (i) laterally trimming the first patterning layer to expose an additional portion of the hard mask layer and (ii) performing a partial etch of the exposed portions of the hard mask layer, and removing the first patterning layer. Forming the asymmetric insulating layer may further include forming a second patterning layer over a portion of the hard mask layer not covering the drain region, etching an exposed portion of the hard mask layer, removing the second patterning layer, and transferring a pattern of the hard mask layer to the insulating material. At least one of the first patterning layer and the second patterning layer may be a photoresist material.

Forming the asymmetric insulating layer may alternatively include forming an insulating material for the insulating layer over the semiconductor layer, forming a photoresist layer over the insulating material, generating a pattern in the photoresist layer utilizing a mask device comprising a light-passing substrate and a patterned opaque layer disposed on the light-passing substrate, the patterned opaque layer comprising a light modulating region for defining the first slope of the first sidewall and the second slope of the second sidewall, and transferring the pattern of the photoresist layer to the insulating material. The light modulating region includes a set of features, wherein at least a subset of the set of features are disposed at differing distances from one another for defining at least one of the first slope of the first sidewall and the second slope of the second sidewall.

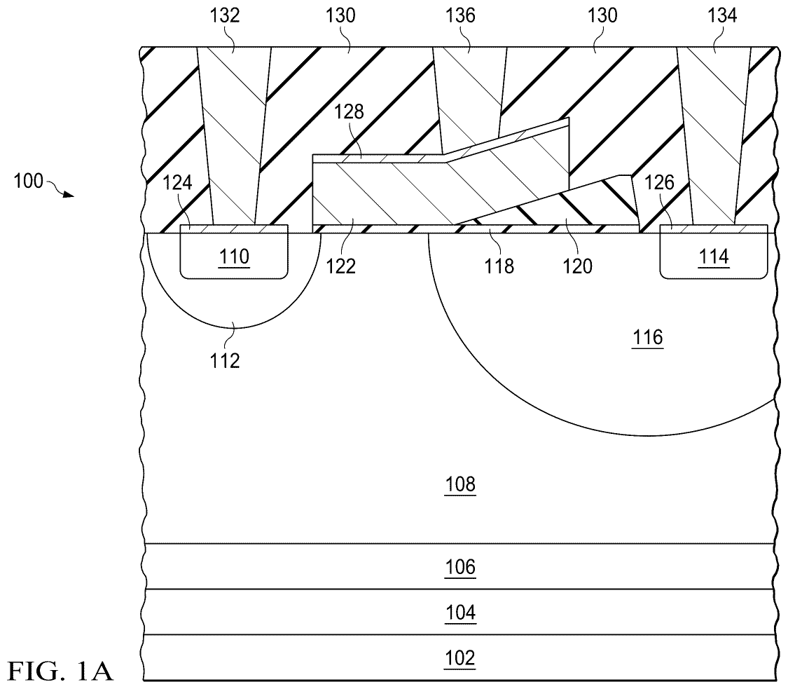

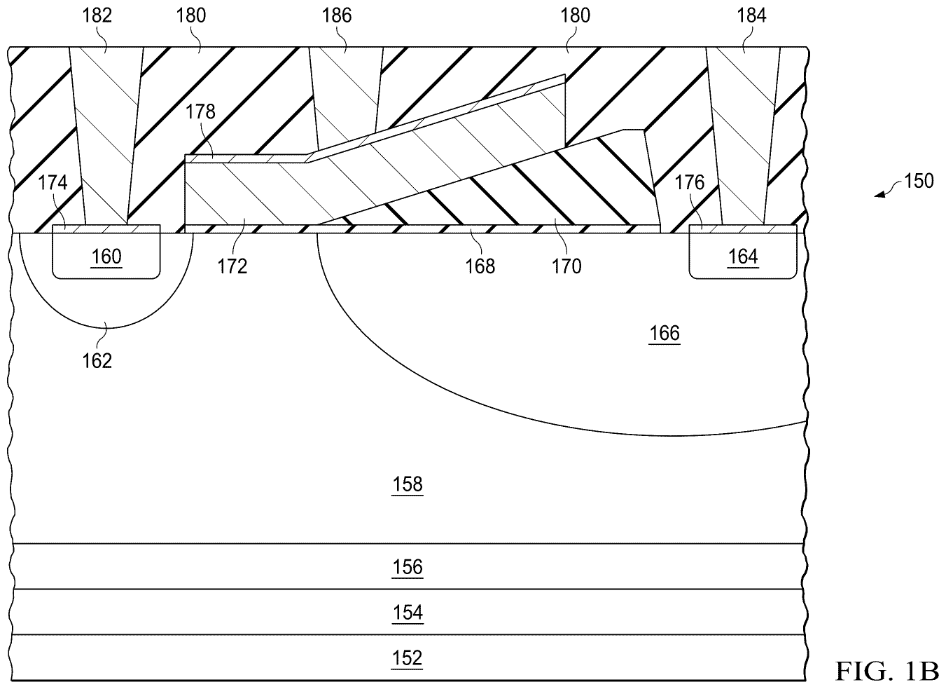

Referring now to FIG. 1A, a cross-sectional view of an LDMOS device 100 is shown. The LDMOS device 100 includes a substrate 102, a first buried layer 104, a second buried layer 106, and a semiconductor layer 108, e.g., formed by an epitaxial process in some examples, and thus referred to as an epitaxial or “epi” layer 108 in such examples. The LDMOS device 100 also includes a source region 110 and a well region 112. The well region 112 is disposed in the epi layer 108, and the source region 110 is disposed in the well region 112. The LDMOS device 100 further includes a drain region 114 and a drain drift region 116. The drain drift region 116 is disposed in the epi layer 108, and the drain region 114 is disposed in the drain drift region 116. The LDMOS device 100 further includes a first insulating layer 118, a second insulating layer 120, and a gate electrode 122. The first insulating layer 118, which may be referred to as a gate dielectric or a gate insulator 118, is disposed between at least a portion of the gate electrode 122 and the epi layer 108, and between at least a portion of the second insulating layer 120 and the epi layer 108. The second insulating layer 120 is asymmetric, and may also be referred to as an asymmetric graded field dielectric or dielectric layer 120. A channel region may be considered to extend across a portion of the epi layer 108 under the gate electrode 122 between the source region 110 and the drain region 114.

In some examples, the substrate 102, the second buried layer 106, the epi layer 108 and the well region 112 have a first conductivity (e.g., one of p-type and n-type), while the first buried layer 104, the source region 110, the drain region 114 and the drain drift region 116 have a second conductivity (e.g., the other of p-type and n-type). While two buried layers, e.g., the first buried layer 104 and the second buried layer 106, are shown, other examples may include one or the other of the buried layers, or no buried layer at all.

The gate electrode 122 is disposed over the gate insulator 118 and at least a portion of the asymmetric graded dielectric layer 120. In some examples, the gate electrode 122 is a polysilicon material. In other examples, the gate electrode 122 is a metal or other suitable material. As shown in FIG. 1A, the gate electrode 122 extends past a first edge of the asymmetric graded dielectric layer 120 towards the source region 110. In some examples, a second edge of the asymmetric graded dielectric layer 120 extends past an edge of the gate electrode 122 towards the drain region 114. In other examples, the second edge of the asymmetric graded dielectric layer 120 does not extend past the edge of the gate electrode 122 towards the drain region 114. Thus, the gate electrode 122 may terminate closer to the source region 110 or the drain region 114 than shown in FIG. 1A. In some examples, the gate electrode 122 may terminate adjacent the source region 110 and/or the drain region 114, rather than being spaced apart from the source region 110 and/or the drain region 114 as shown in FIG. 1A.

Silicide layers 124, 126 and 128 are disposed in contact with the source region 110, the drain region 114 and the gate electrode 122, respectively. The silicide layers 124, 126 and 128 provide ohmic contacts and high conductivity.

An interlayer dielectric (ILD) 130 is disposed over the structure, and conductive vias 132, 134 and 136 are disposed in the ILD 130 to contact the silicide layers 124, 126 and 128, respectively.

Referring now to FIG. 1B, a cross-sectional view of an LDMOS device 150 is shown. The LDMOS device 150 may be considered a device for higher voltage applications than LDMOS device 100, as further described below. The LDMOS device 150 includes a substrate 152, a first buried layer 154, a second buried layer 156, and a semiconductor layer 158, e.g., formed by an epitaxial process in some examples, and thus referred to as an epitaxial or “epi” layer 158 in such examples. The LDMOS device 150 also includes a source region 160, a well region 162, a drain region 164, a drain drift region 166, a first insulating layer 168 also referred to as a gate insulator 168, and a second insulating layer 170 also referred to as an asymmetric graded dielectric layer 170, disposed between a gate electrode 172 and the epi layer 158. A channel region may be considered to extend across a portion of the epi layer 158 under the gate electrode 172 between the source region 160 and the drain region 164. The LDMOS device 150 further includes silicide layers 174, 176 and 178 disposed in contact with the source region 160, the drain region 164 and the gate electrode 172, respectively. An ILD 180 is disposed over the structure, and conductive vias 182, 184 and 186 are disposed in the ILD 180 to contact the silicide layers 174, 176 and 178, respectively.

The substrate 152, the first buried layer 154, the second buried layer 156, the epi layer 158, the source region 160, the well region 162, the drain region 164, the drain drift region 166, the gate insulator 168, the gate electrode 172, the silicide layers 174, 176 and 178, the ILD 180, and the conductive vias 182, 184 and 186 are similar to the substrate 102, the first buried layer 104, the second buried layer 106, the epi layer 108, the source region 110, the well region 112, the drain region 114, the drain drift region 116, the gate insulator 118, the gate electrode 122, the silicide layers 124, 126 and 128, the ILD 130, and the conductive vias 132, 134 and 136, respectively.

The asymmetric graded dielectric layer 170 may be formed of similar materials as the asymmetric graded dielectric layer 120, but has a different shape. The asymmetric graded dielectric layer 120 and the asymmetric graded dielectric layer 170 have different heights or thicknesses, as well as different lateral widths. In some examples, however, the asymmetric graded dielectric layer 120 and the asymmetric graded dielectric layer 170 have different heights or thicknesses but the same lateral width, or the same height or thickness but different lateral widths. The asymmetric graded dielectric layer 170 may also include a longer non-sloped portion (e.g., a horizontal or flat portion, with a slope of at or about zero degrees) than the asymmetric graded dielectric layer 120. The asymmetric graded dielectric layer 170, having a larger height or thickness and lateral width, provides greater field relief dielectric properties than the asymmetric graded dielectric layer 120 such that that the asymmetric graded dielectric layer 170 is more suited for use with relatively high voltage (HV) applications. In some examples, the LDMOS device 100 is a relatively low voltage (LV) LDMOS device, while the LDMOS device 150 is a relatively HV LDMOS device. The LDMOS device 100 and the LDMOS device 150, in some examples, are formed on different portions of a same wafer or semiconductor structure (e.g., such that the substrates 102 and 152 are the same, as well as possibly other layers such as the ILDs 130 and 180). For LDMOS devices designed for relatively HV use, the sizing (e.g., height or thickness and lateral width) of the asymmetric graded dielectric layer 170 provides improved Rsp and BV characteristics. The height or thickness and lateral scaling of an asymmetric graded dielectric layer may be based on the expected voltage or power requirements of LDMOS devices.

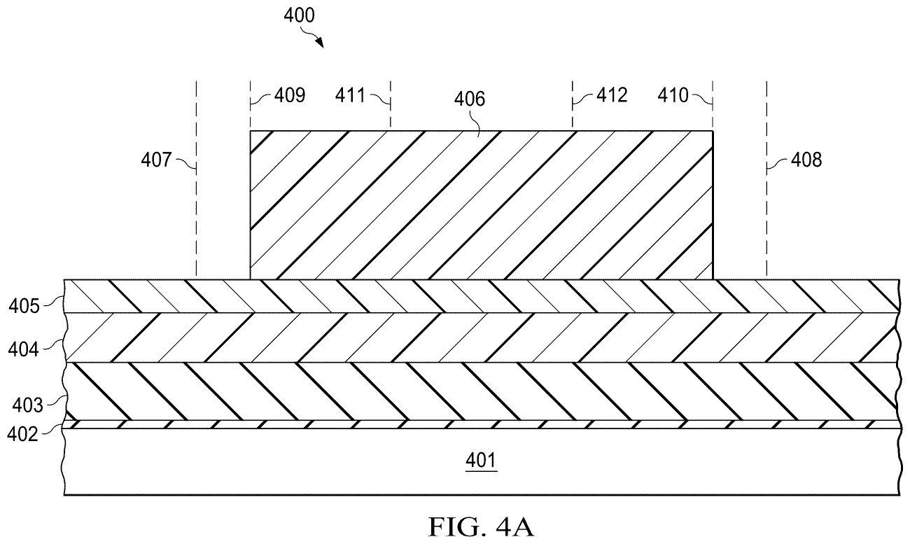

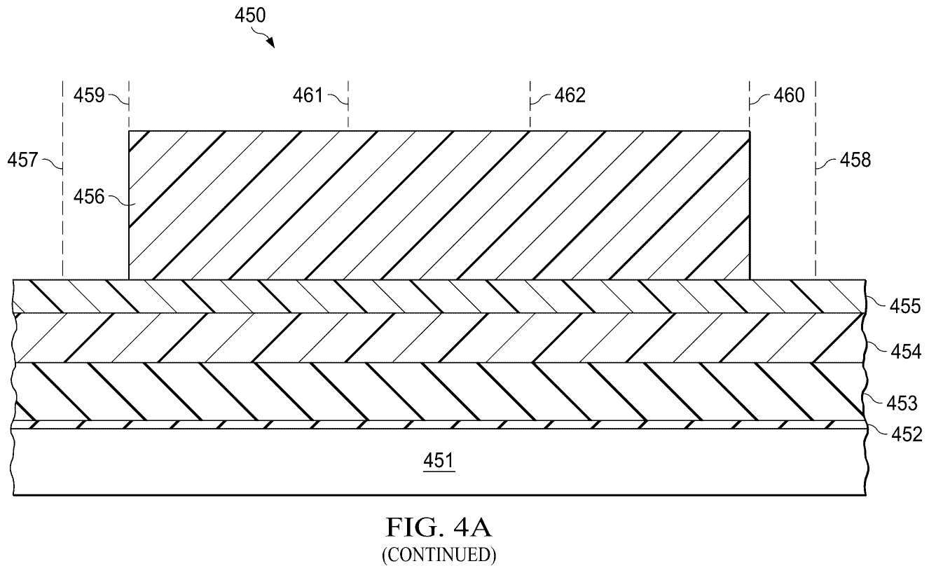

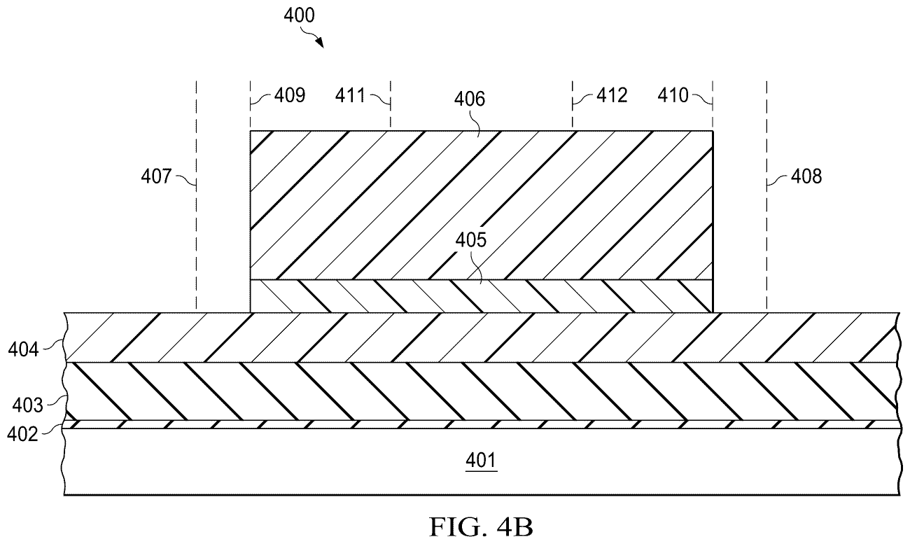

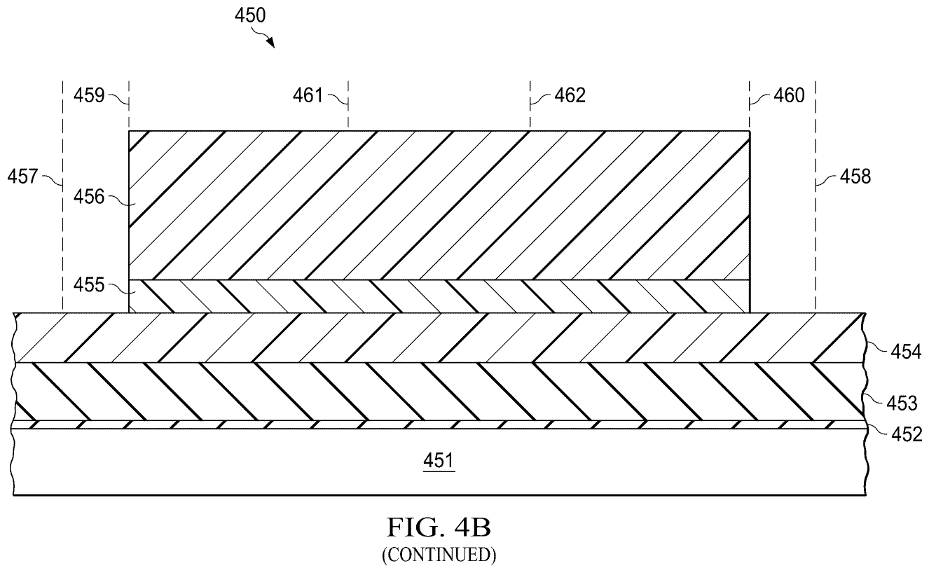

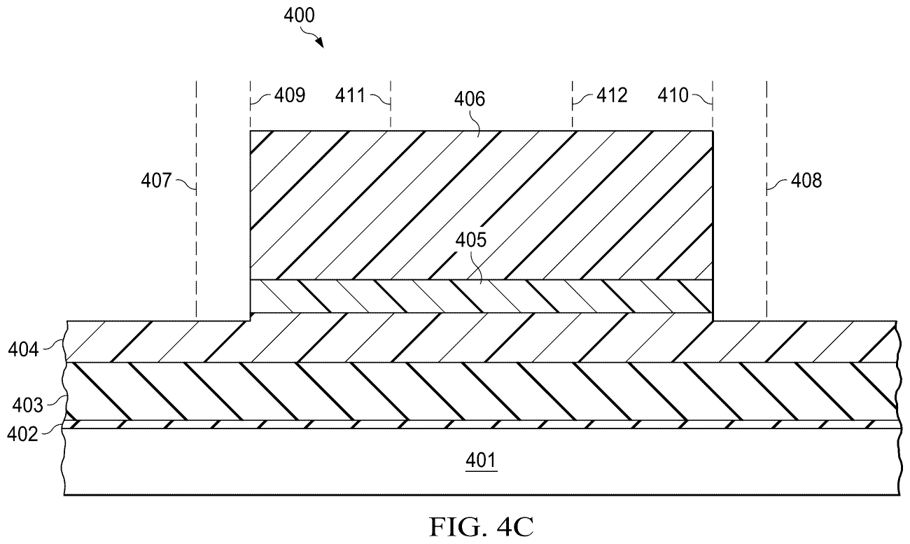

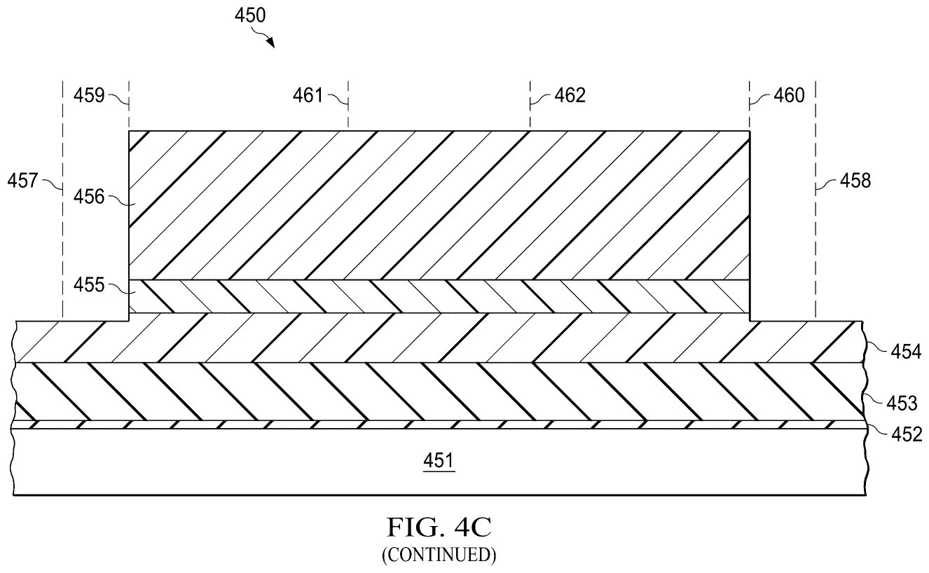

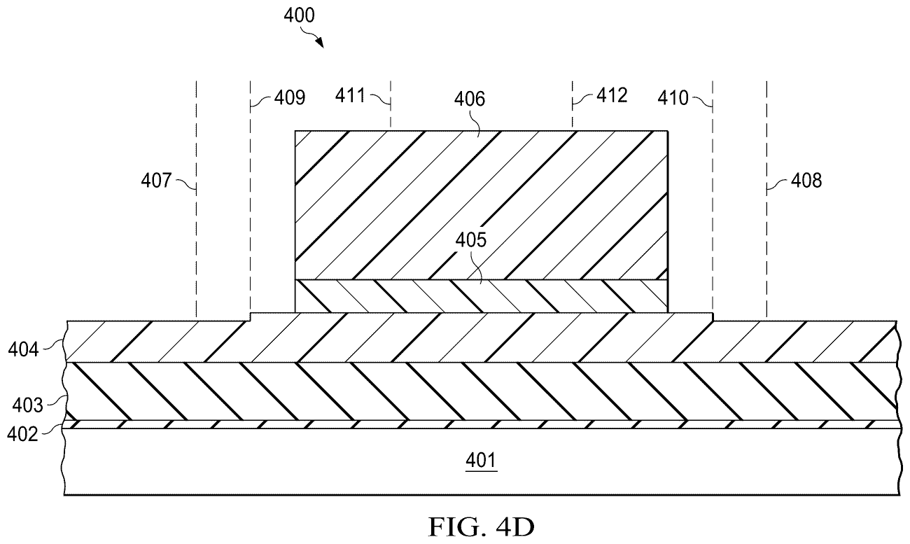

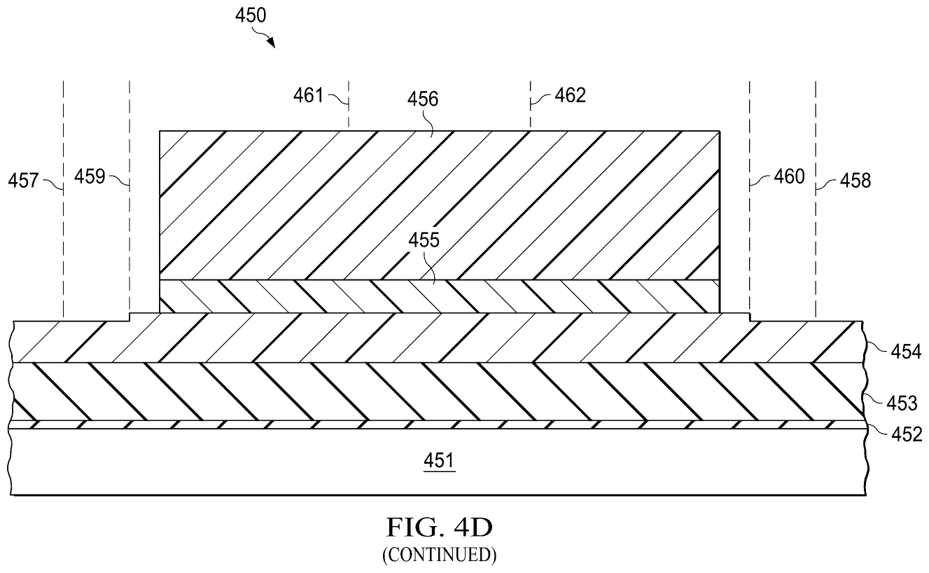

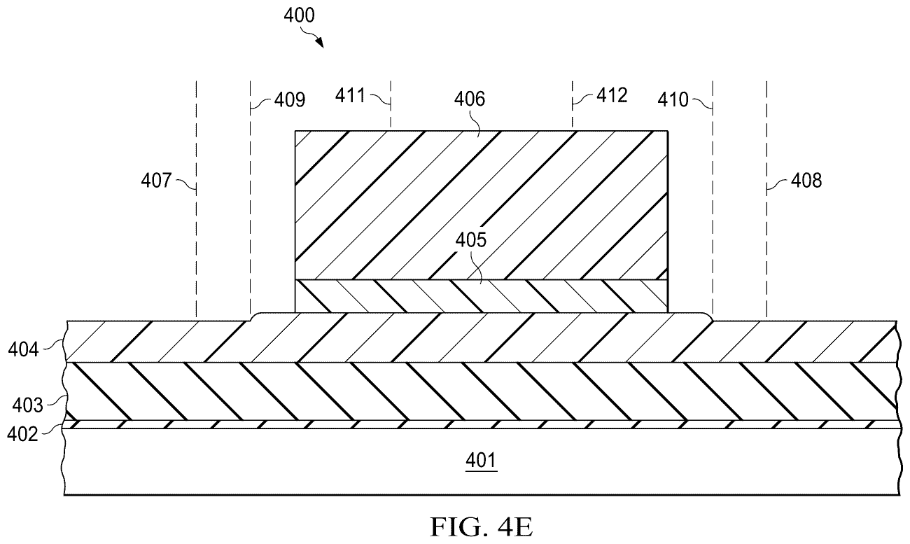

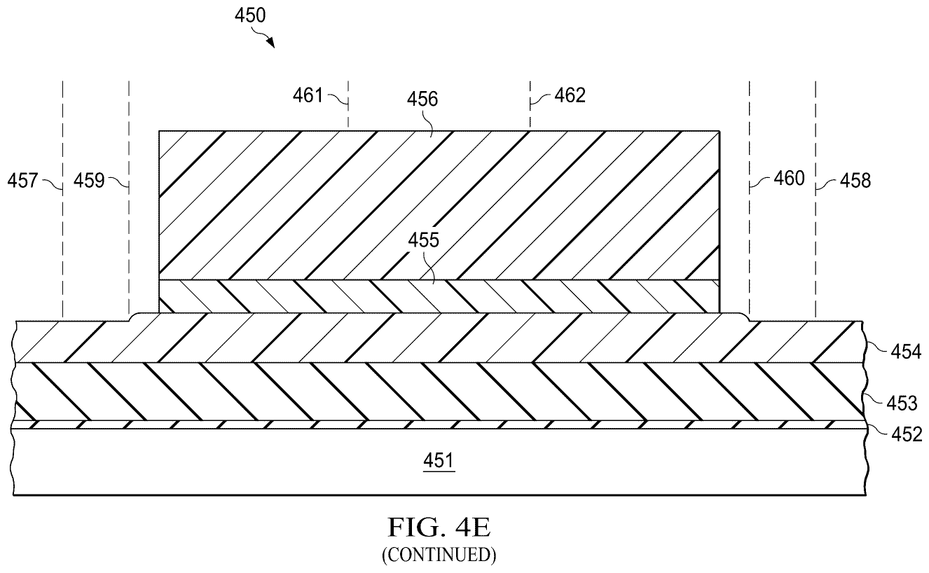

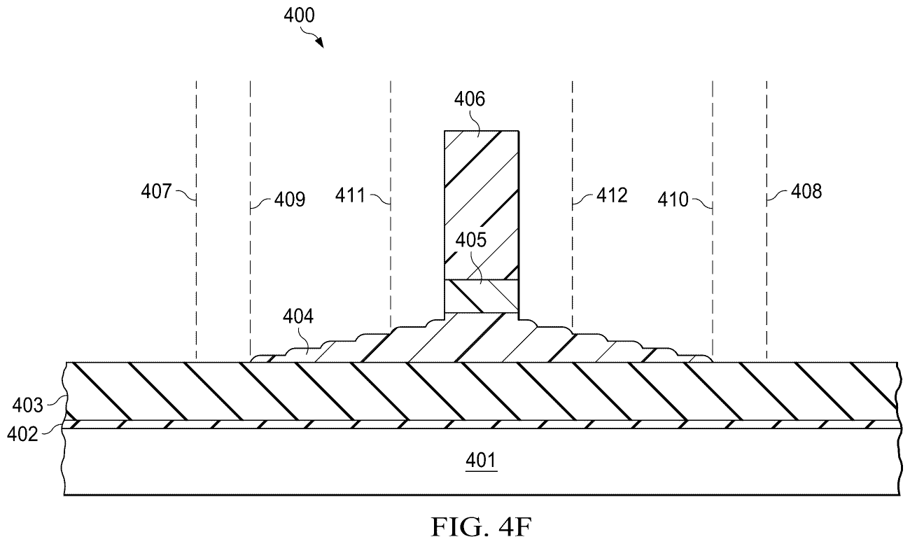

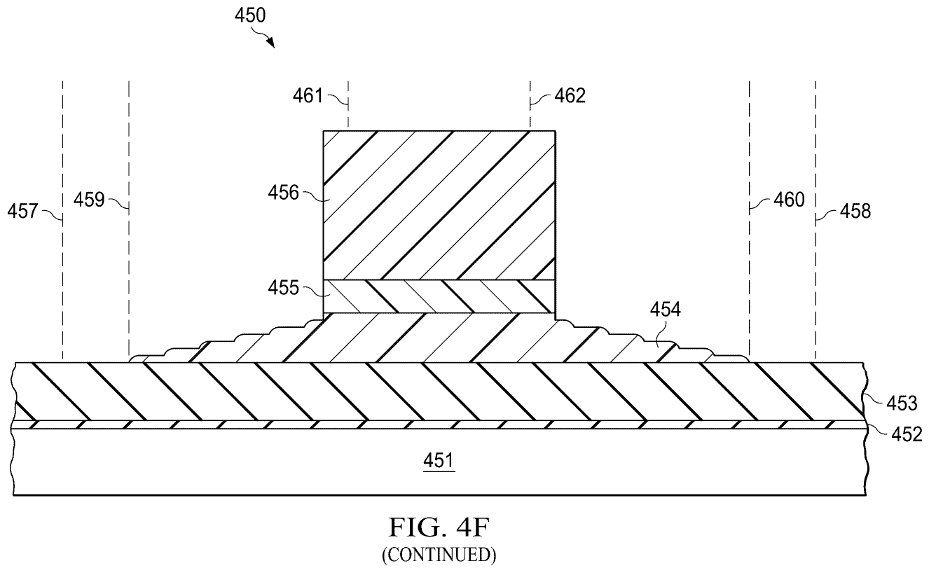

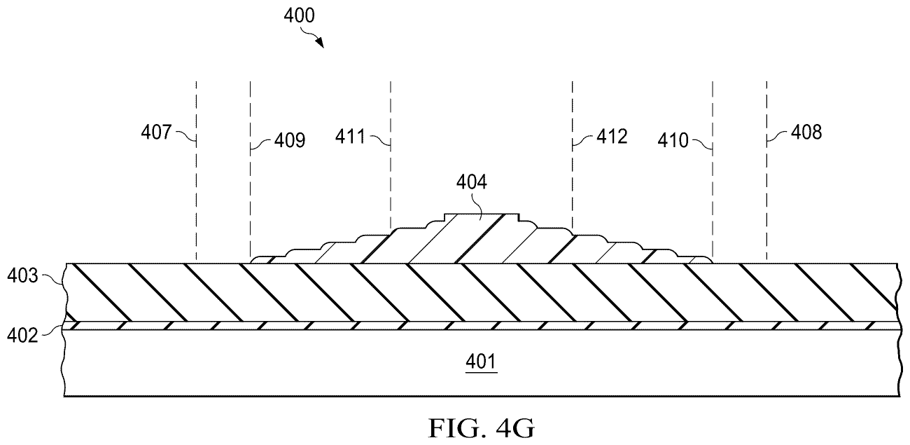

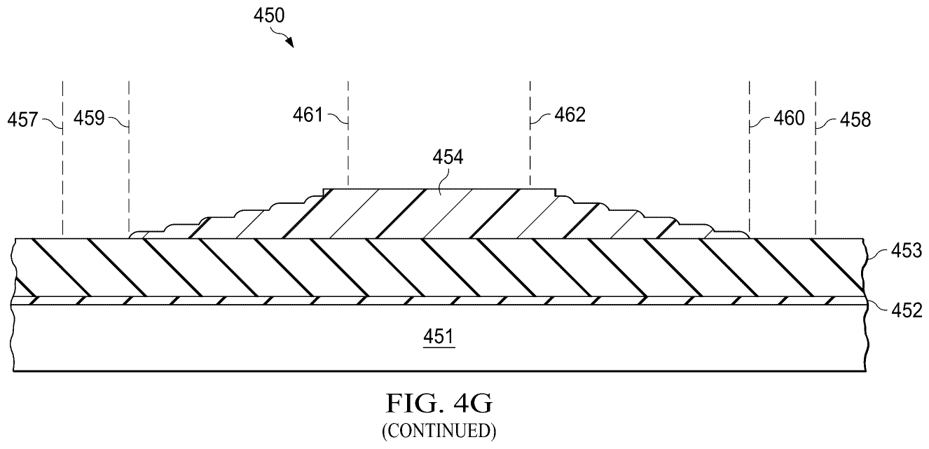

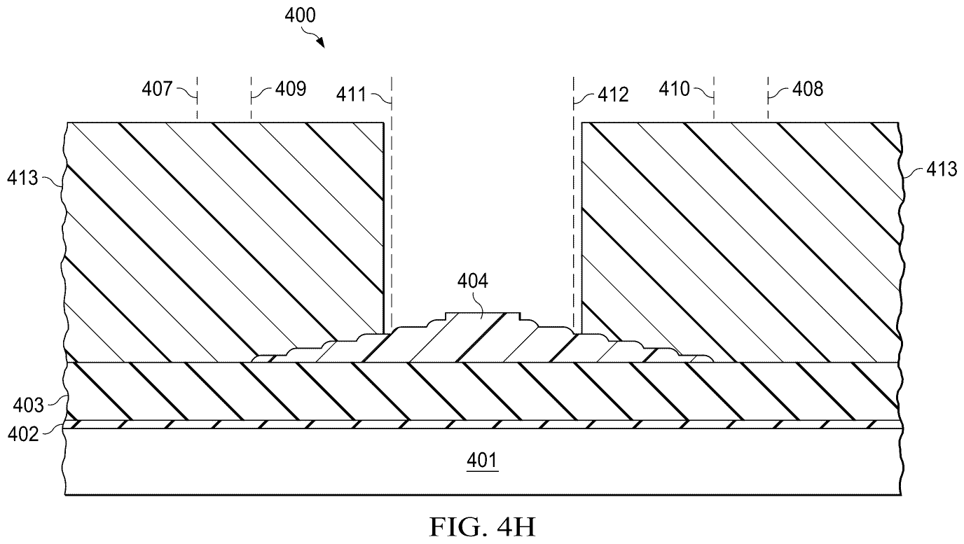

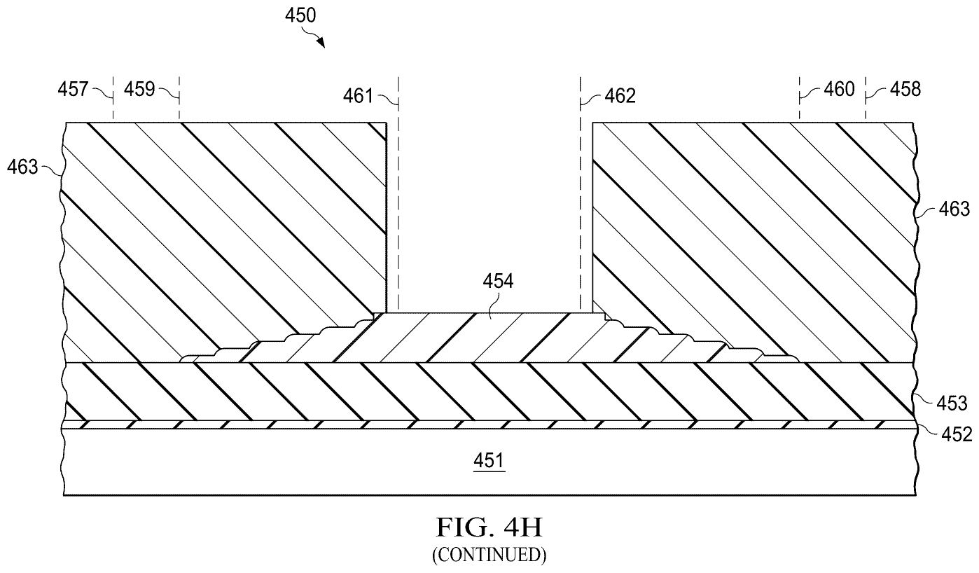

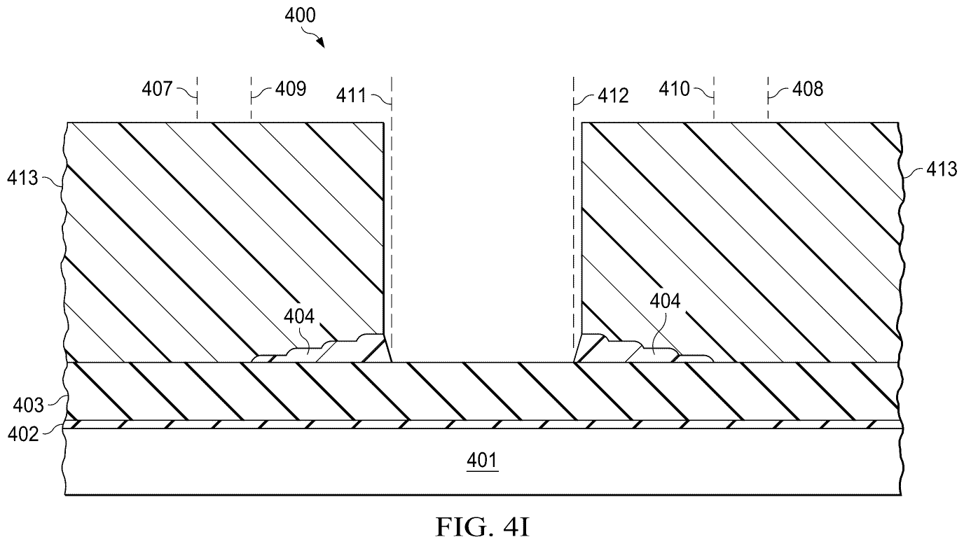

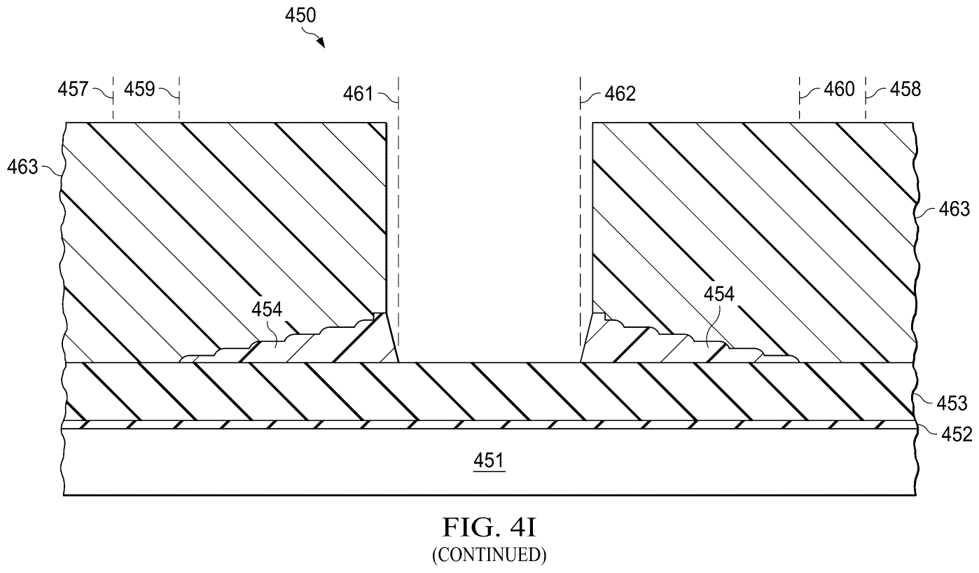

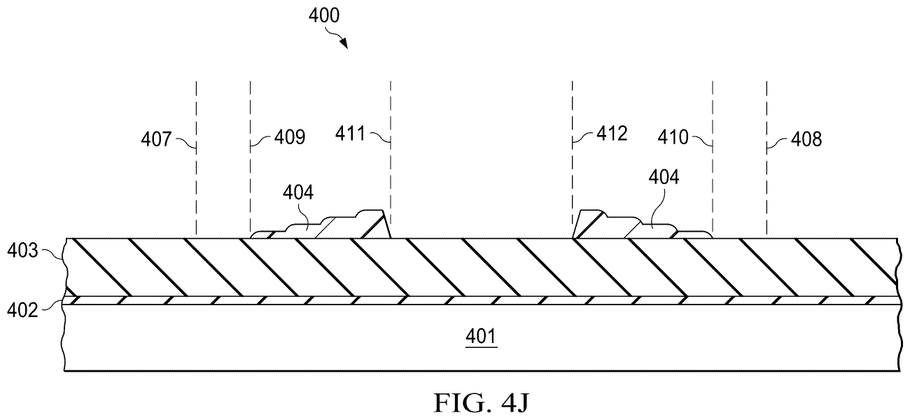

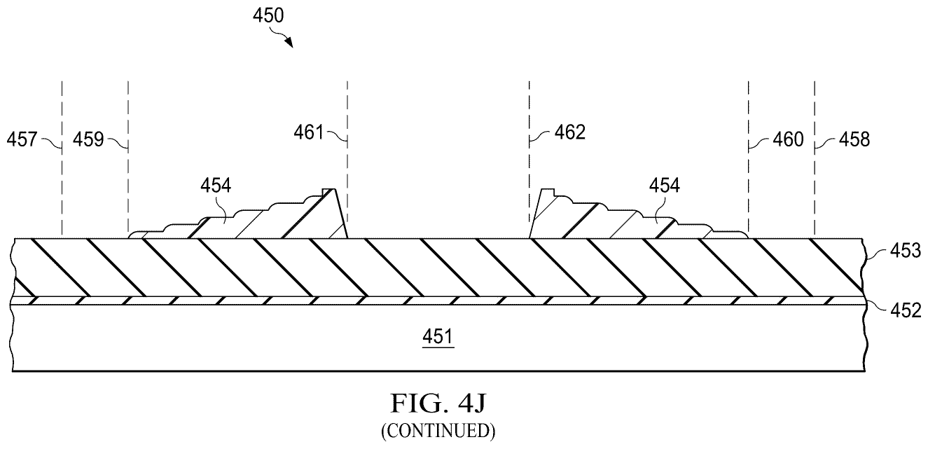

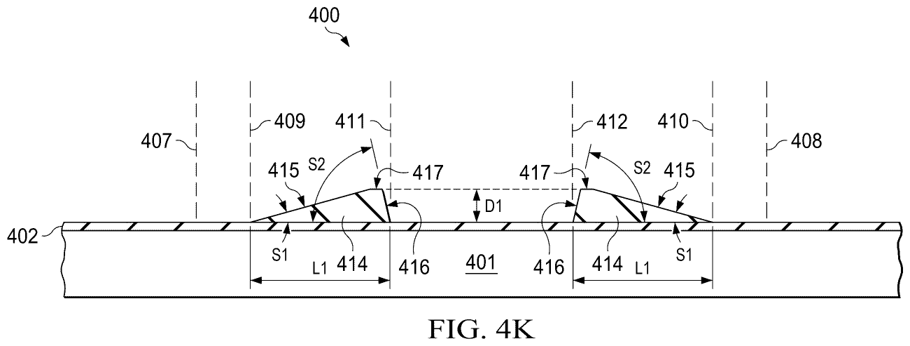

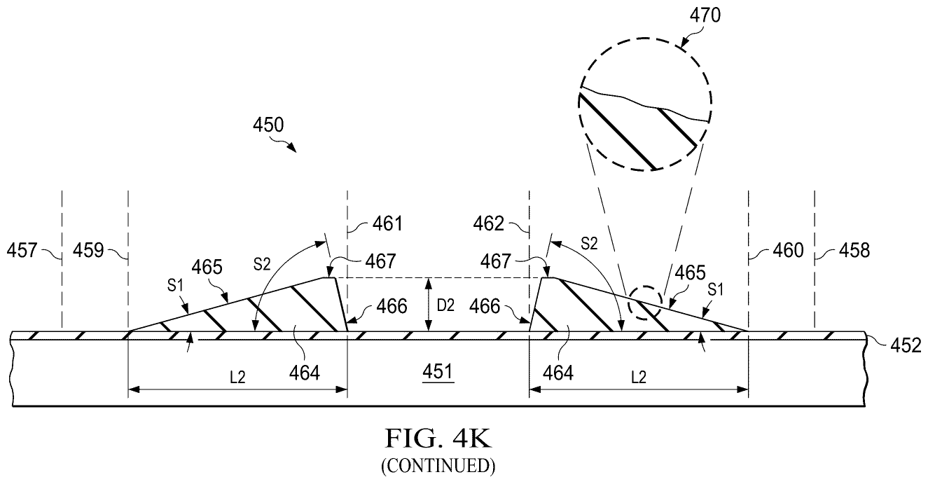

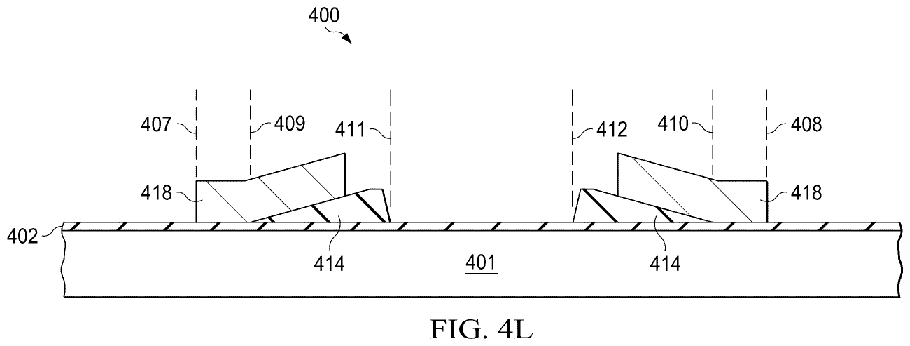

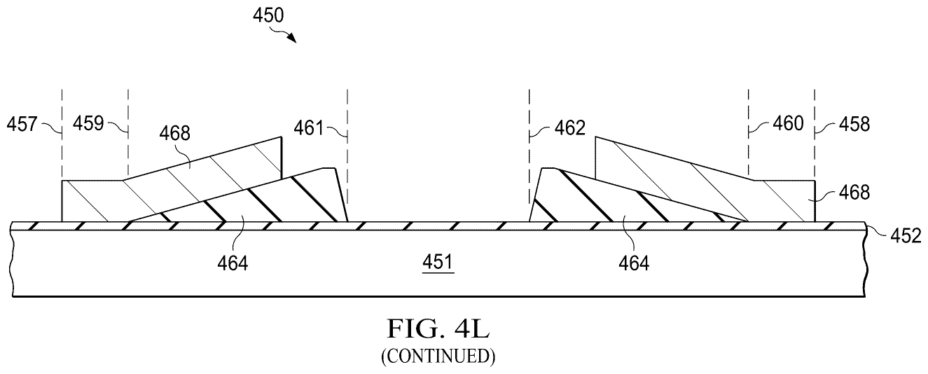

Semiconductor structures with asymmetric graded dielectric layers may be formed using various processing flows. In some examples (e.g., the processing flow described in further detail below with respect to FIGS. 4A-4L), two masks are used to achieve the asymmetric shape of asymmetric graded dielectric layers—a first mask which is used to pattern the shallow sloped or graded edge (e.g., the sidewalls extending toward the source regions) and a second mask which is used to open the drain region between the two sloped sides of the asymmetric graded dielectric layers. Both sides of the first mask (e.g., the photoresist pattern) will form shallow slopes. The drain region is covered by the first mask while the shallow-sloped side of two asymmetric graded dielectric layers are formed on either side of a drain region. The second mask is used to open the drain region between two sloped sides of the trapezoidal dielectric formed using the first mask. The second mask thus forms the steep-sloped side of asymmetric graded dielectric layers (the sidewalls extending toward the drain region). The first and second masks are used to create a pattern in a sacrificial hard mask layer, with the pattern then being transferred into an insulating material (e.g., an oxide or other suitable dielectric material) used for the asymmetric graded dielectric layers. The natural faceting of a plasma etch processing will result in smoothing of the profile during this transfer step. The height of the asymmetric graded dielectric layers can be controlled by a degree of overlap between the first and second masks. The slope of all asymmetric graded dielectric layers which are formed at the same time will be approximately the same. More mask overlap between the first and second masks results in a lower width and height for asymmetric graded dielectric layers, though all asymmetric graded dielectric layers formed at the same time will have the same height/width ratio. For devices that are not symmetric about a drain region, a dummy asymmetric graded dielectric layer will be created.

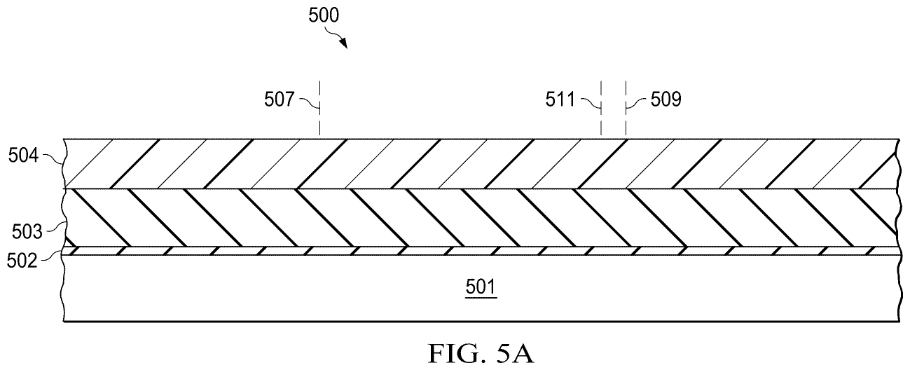

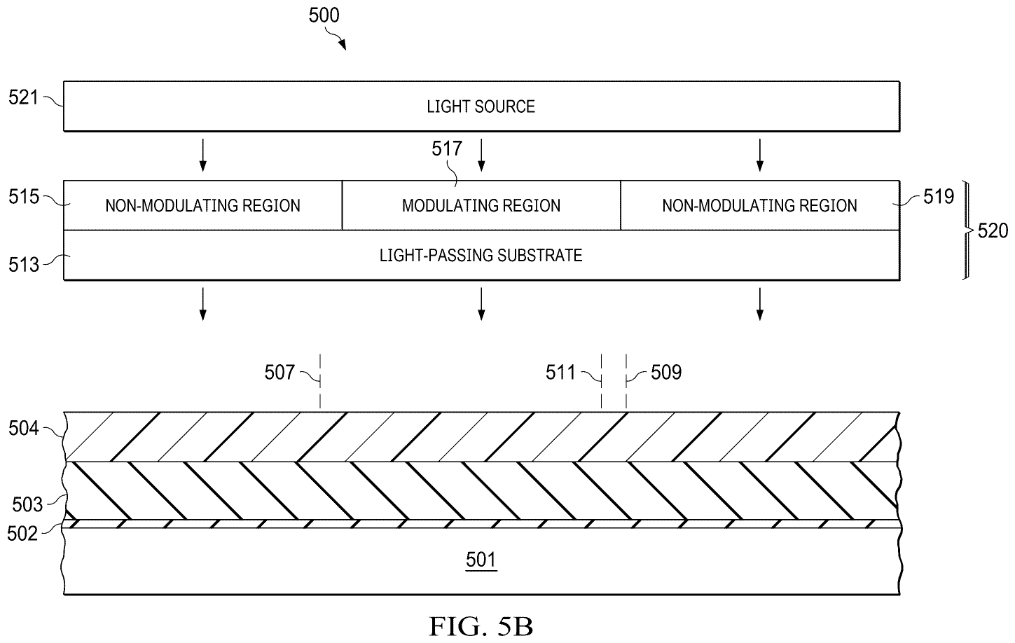

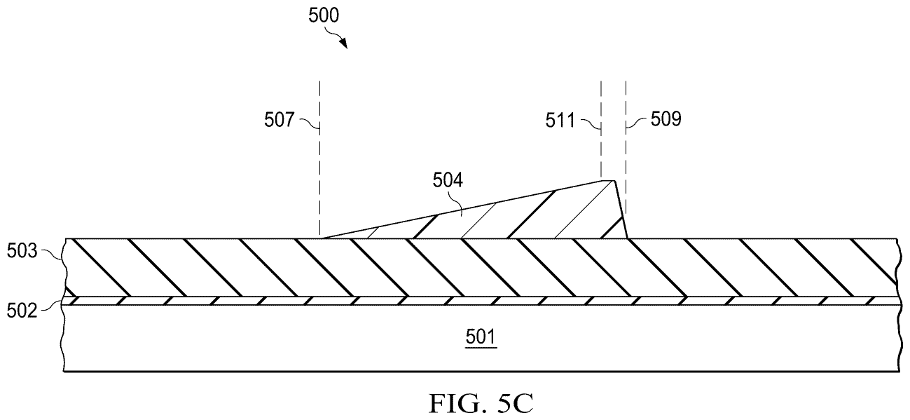

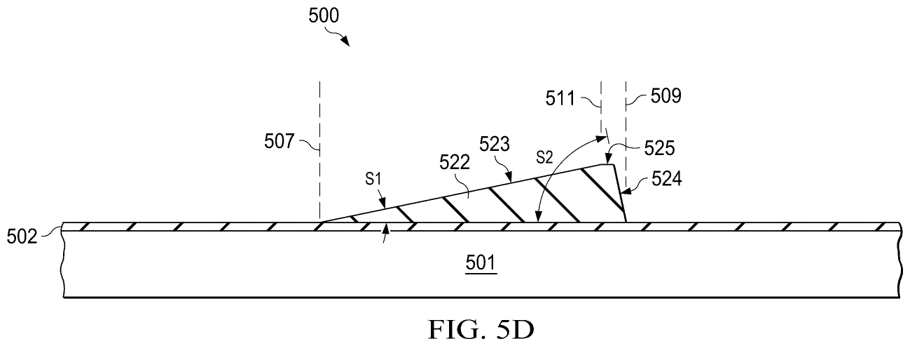

In other examples (e.g., the process flow of FIGS. 5A-5D), photolithographic mask devices are used to form asymmetric graded dielectric layers. A form of photolithography, referred to as grayscale photolithography, facilitates three-dimensional (3D) structure shaping, e.g., structures defined in x and y dimensions on a plane with non-perpendicular (e.g., sloped, tapered, contoured) sidewall profiles.

More particularly, grayscale mask-based lithography uses a mask device (e.g., sometimes referred to as a grayscale mask or grayscale reticle) to spatially modulate or modify the light intensity or dosage applied to a photoresist layer formed on an underlying layer of the device being fabricated. By way of example, the light applied to the grayscale mask device typically is ultra-violet (UV) light. Modulation of the light is enabled by a patterned opaque layer disposed on a light-passing substrate. The patterned opaque layer includes areas of opaque material (opaque areas of the patterned opaque layer) and areas without opaque material (open areas of the patterned opaque layer where a surface of the light-passing substrate is exposed). For example, the opaque areas can be composed of a metal material such as, but not limited to, chrome, chromium, and/or a metal oxide. The light-passing substrate can be composed of a light-passing material such as, but not limited to, quartz, fused silica, and/or glass. Thus, in one example, a grayscale mask device can be fabricated where chrome serves as the opaque material and glass serves as the light-passing material. Such a mask device is sometimes referred to as a chrome-on-glass (COG) mask. In general, such a mask can also be referred to as a binary mask given its functionality to block light in certain areas and pass light in other areas.

During the grayscale photolithographic process, the applied light is blocked or obstructed by opaque areas of the patterned opaque layer while passing through the open areas and then through the substrate. More particularly, grayscale mask devices rely on the concept of diffraction where light bends or spreads around the edges of the opaque areas while passing through the open areas of the patterned opaque layer.

Accordingly, the term “opaque,” as illustratively used herein, refers to a characteristic of a material to block applied light by reflection, absorption, and/or some other light-blocking functionality. The term “light-passing,” as illustratively used herein, refers to a characteristic of a material to enable all or most of the applied light to pass (e.g., transparent material) or some portion of the applied light to pass (e.g., translucent or semitransparent material).

In a clear field mask, the pattern features formed in the patterned opaque layer on a surface of the light-passing substrate are composed of opaque material and thus block light, while clear or open areas (lack of opaque material) expose the surface of the light-passing substrate and thus pass light. In contrast, in a dark field mask, the pattern features on the surface are clear or open areas (pass light) while the other areas on the surface are opaque material and thus block light. Depending on the structures being fabricated in the underlying device, either type of mask device (clear field or dark field) can be used with a positive photoresist material or a negative photoresist material.

The modulated light passing through the mask device, e.g., measured as an intensity-pass percentage, correspondingly modulates or modifies the amount of photosensitive material that is removed (positive photoresist) or remains (negative photoresist) in the photoresist layer to form a profile in the photoresist layer. Thus, in a positive photoresist example, the more light that passes through the mask device (e.g., higher intensity-pass percentage) onto the photoresist layer, the more photosensitive material of the photoresist layer is removed during development (e.g., decreasing the thickness of the photoresist layer from its original thickness). Thus, by modulating the applied light to change the exposure dose or intensity locally in the photoresist layer, profiles can be selectively formed in the photoresist layer, e.g., non-perpendicular photoresist sidewall profiles. The profiles can then be transferred to the underlying layer of the semiconductor device to fabricate various structures of the semiconductor device, such as trenches for asymmetric graded dielectric layers.

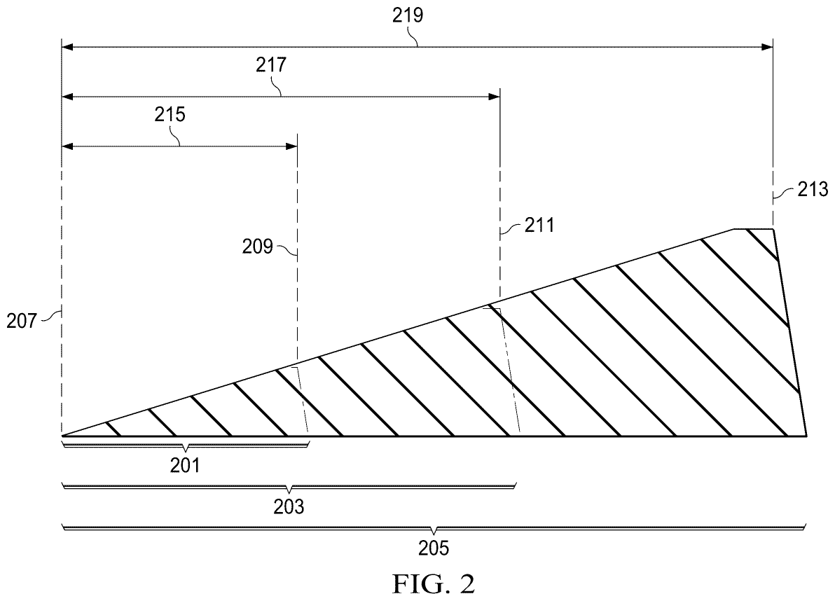

The slope of the shallow-sloped side of the asymmetric graded dielectric layer is tied to process parameters, and will approximately match for all devices formed at the same time (e.g., on a same wafer). Scaling of the asymmetric graded dielectric layer along this slope (e.g., with the same height/width ratio) can be achieved by varying the overlap between the first and second masks (e.g., in the process flow of FIGS. 4A-4L), where more overlap results in a smaller width and height for the asymmetric graded dielectric layer. FIG. 2 illustrates such scaling, including an asymmetric graded dielectric layer 201 for LV devices, an asymmetric graded dielectric layer 203 for medium voltage (MV) devices, and an asymmetric graded dielectric layer 205 for HV devices. FIG. 2 also shows mask edges 207, 209, 211 and 213. The mask edge 207 is the source-side mask edge, the mask edge 209 is the drain-side mask edge for LV devices, the mask edge 211 is the drain-side mask edge for MV devices, and the mask edge 213 is the drain-side mask edge for HV devices. FIG. 2 further shows widths 215, 217 and 219. Width 215 is the width of the asymmetric graded dielectric layer 201 for LV devices, width 217 is the width of the asymmetric graded dielectric layer 203 for MV devices, and width 219 is the width of the asymmetric graded dielectric layer 205 for HV devices. It should be noted that varying the sets of features in a modulating region of a grayscale mask device (e.g., in the process flow of FIGS. 5A-5D) may similarly be used for controlling the slope of asymmetric graded dielectric layers.

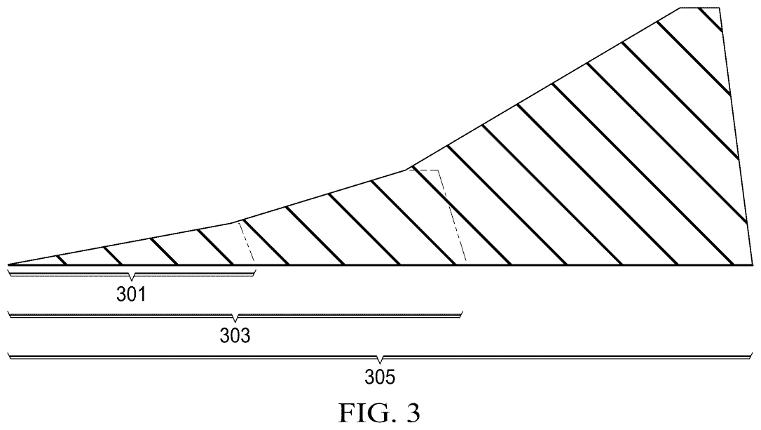

In some examples, the shallow-sloped side of the asymmetric graded dielectric layer is multi-sloped (e.g., a composite of two or more component slopes). FIG. 3 illustrates multi-sloped asymmetric graded dielectric layers, including an asymmetric graded dielectric layer 301 for LV devices, an asymmetric graded dielectric layer 303 for MV devices, and an asymmetric graded dielectric layer 305 for HV devices. As shown in FIG. 3, the asymmetric graded dielectric layer 303 for MV devices and the asymmetric graded dielectric layer 305 for HV devices are multi-sloped. The slope of the asymmetric graded dielectric layer 303 is a composite of the lower slope of asymmetric graded dielectric layer 301 and a higher slope, and the slope of the asymmetric graded dielectric layer 305 is a composite of the lower slopes of the asymmetric graded dielectric layers 301 and 303.

Process flows for forming asymmetric graded field relief dielectric layers, e.g., asymmetric graded dielectric layers 120 and 170 shown in FIGS. 1A and 1B, will now be described with respect to FIGS. 4A-5E.

FIG. 4A shows a cross-sectional view of structures 400 and 450, which include semiconductor layers 401 and 451, padding layers 402 and 452, insulating material 403 and 453, hard mask layers 404 and 454, optional organic hard mask layers 405 and 455, and photoresist layers 406 and 456. The structure 400 may be used for forming a relatively LV LDMOS device (e.g., LDMOS device 100 of FIG. 1A), while the structure 450 may be used for forming a relatively HV LDMOS device (e.g., LDMOS device 150 of FIG. 1B). In some examples, the LV and HV LDMOS devices can be formed at the same (or substantially the same) time in different portions of a structure, where the semiconductor layers 401 and 451, the padding layers 402 and 452, the insulating material 403 and 453, the hard mask layers 404 and 454, and the organic hard mask layers 405 and 455 are the same. The photoresist layers 406 and 456 are formed in different areas for defining the edges of the thin side of asymmetric graded dielectric layers for the LV and HV LDMOS devices.

The semiconductor layers 401 and 451 may be formed of silicon (Si) or another suitable semiconductor material. In some examples, the semiconductor layers 401 and 451 are formed using an epitaxial growth process and are thus referred to as epitaxial or “epi” layers 401 and 451.

The padding layers 402 and 452 may be formed of an oxide or other suitable material. The padding layers 402 and 452 are blanket deposited over the epi layers 401 and 451. The padding layers 402 and 452 may have a thickness in the range of, for example, 50-150 angstroms (Å).

The insulating material 403 and 453 may be formed of an oxide or other suitable dielectric material that will be used for the asymmetric graded dielectric layers that are to be formed. The insulating material 403 and 453 may have a thickness or height that is sufficient for accommodating the desired height of the asymmetric graded dielectric layers that are to be formed. The insulating material 403 and 453 is blanket deposited over the padding layers 402 and 452.

The hard mask layers 404 and 454 may be formed of a nitride material, and may be referred to as nitride hard mask layers 404 and 454. The nitride hard mask layers 404 and 454 are blanket deposited over the insulating material 403 and 453. The nitride hard mask layers 404 and 454 have a thickness which is sufficient for transferring a pattern of a desired depth for the asymmetric graded dielectric layers. In some examples, the nitride hard mask layers 404 and 454 have a thickness that is similar to the desired thickness of the asymmetric graded dielectric layers which are to be formed in the structures 400 and 450, so that the transfer etch (e.g., from the nitride hard mask layers 404 and 454 to the insulating material 403 and 453) may utilize a non-selective plasma etch process. In other examples, the nitride hard mask layers 404 and 454 may be thicker or thinner than the desired thickness of the asymmetric graded dielectric layers which are to be formed in the structures 400 and 450, if the plasma etch process selectivity is modified.

The organic hard mask layers 405 and 455 are blanket deposited over the nitride hard mask layers 404 and 454. The organic hard mask layers 405 and 455 have a height or thickness in the range of, for example, 200-1000 Å. The organic hard mask layers 405 and 455 are optional layers. In some examples, the organic hard mask layers 405 and 455 comprise an organic bottom anti-reflective coating (BARC) material, and thus may be referred to as organic BARC layers 405 and 455. In other examples, the organic hard mask layers 405 and 455 comprise multi-layer resist (MLR) organic hard masks.

The photoresist layers 406 and 456 may be formed of a photoresist material. The photoresist layers 406 and 456 are patterned to align with the thin side of the asymmetric graded dielectric layers that are to be formed, and cover the entire regions of the epi layers 401 and 451 where drain and drain drift regions are or will be formed. Asymmetric graded dielectric layers will be formed at either edge of the photoresist layers 406 and 456. For devices that are not mirrored about the drain, a dummy asymmetric graded dielectric layer will be created. In some examples, the dummy asymmetric graded dielectric layers are retained in the structure. In other examples, the dummy asymmetric graded dielectric layers are removed during a drain opening step. FIG. 4A shows dashed lines 407, 408, 409, 410, 411, 412, 457, 458, 459, 460, 461 and 462. Dashed lines 407, 408, 457 and 458 define the source-side gate electrode edges. Dashed lines 409, 410, 459 and 460 define the source-side drain drift region edges. Dashed lines 411, 412, 461 and 462 define drain region edges.

FIG. 4B shows a cross-sectional view of the structures of FIG. 4A following etching portions of the organic BARC layers 405 and 455 which are exposed by the photoresist layers 406 and 456. The etching of the organic BARC layers 405 and 455 may be etched using a dry etch or other suitable processing. This etching of the organic BARC layers 405 and 455 exposes a portion of the top surface of the nitride hard mask layers 404 and 454.

FIG. 4C shows a cross-sectional view of the structures of FIG. 4B following a partial etching of the exposed portions of the nitride hard mask layers 404 and 454. This etching may utilize a short nitride dry etch. The depth of the partial etching of the exposed portion of the nitride hard mask layers 404 and 454 may be a designated percentage of the thickness of the nitride hard mask layers 404 and 454 which will be based on the number of trim-and-etch cycles that are utilized. In some examples, the designated percentage is 5-33% of the thickness of the nitride hard mask layers 404 and 454.

FIG. 4D shows a cross-sectional view of the structures of FIG. 4C following a trim to laterally pull back the photoresist layers 406 and 456 and the organic BARC layers 405 and 455. The trim may be an O₂-based trim cycle, which trims the edge of the photoresist layers 406 and 456 and the organic BARC layers 405 and 455 away from the dashed lines 409, 410, 459 and 460 a distance that is a designated percentage of the final desired width of the shallow-sloped sidewall of the asymmetric graded dielectric layers that are to be formed, where the designated percentage will be based on the number of trim-and-etch cycles that are utilized. In some examples, the designated percentage is 5-33% of the desired width of the asymmetric graded dielectric layers that are to be formed.

FIG. 4E shows a cross-sectional view of the structures of FIG. 4D following another partial etching of the exposed portions of the nitride hard mask layers 404 and 454. This etching may utilize similar processing as that described with respect to FIG. 4C though, as a result of the trim processing described with respect to FIG. 4D, a greater lateral amount of the nitride hard mask layers 404 and 454 are exposed and etched utilizing a short nitride dry etch. The depth of the partial etching of the exposed portion of the nitride hard mask layers 404 and 454 may be similar to that described with respect to FIG. 4C. The partial etching of FIG. 4E may utilize repeated nitride etch cycles, which rounds the exposed corners of the nitride hard mask layers 404 and 454 due to natural etch faceting.

FIG. 4F shows a cross-sectional view of the structures of FIG. 4E following repeated trim-and-etch cycles (e.g., the processing described with respect to FIGS. 4D and 4E) until the underlying insulating material 403 and 453 is reached. The trim and nitride etch times are tuned to achieve a desired profile, e.g., a staircase-like profile. The nitride etch may utilize etch processing that has good selectivity to the material of the insulating material 403 and 453 (e.g., an oxide), to reduce the risk of etch damage to device channels. The nitride etch may also utilize a flat etch front. The slopes of the shallow-sloped sidewalls of the asymmetric graded dielectric layers in both the LV and HV regions will match. The required height of the photoresist layers 406 and 456 is determined by the HV slope length and nitride etch losses, e.g., for an asymmetric graded dielectric layer that is to be formed 150 nanometers (nm) tall and 450 nm wide, at least a 600 nm resist height is used.

FIG. 4G shows a cross-sectional view of the structures of FIG. 4F following strip of the photoresist layers 406 and 456 and the organic BARC layers 405 and 455.

FIG. 4H shows a cross-sectional view of the structures of FIG. 4G following formation of drain patterning masks 413 and 463. The drain patterning masks 413 and 463 may be formed of photoresist, with optional organic hard mask layers, e.g., formed of a BARC or MLR material, as needed for photo capability. The drain patterning masks 413 and 463 are utilized for opening drain regions of the underlying epi layers 401, 451, e.g., to allow for implants and silicide formation.

FIG. 4I shows a cross-sectional view of the structures of FIG. 4H following etching of exposed portions of the nitride hard mask layers 404 and 454 to expose the top surface of the underlying insulating material 403 and 453. The etching of the exposed portions of the nitride hard mask layers 404 and 454 defines a steep slope for steep-sloped sidewalls of the asymmetric graded dielectric layers that are to be formed.

FIG. 4J shows a cross-sectional view of the structures of FIG. 4I following removal of the drain patterning masks 413 and 463.

FIG. 4K shows a cross-sectional view of the structures of FIG. 4J following transfer of the profile of the nitride hard mask layers 404 and 454 into the underlying insulating material 403 and 453 to form asymmetric graded dielectric layers 414 and 464. In some examples, the transfer of the profile of the nitride hard mask layers 404 and 454 into the underlying insulating material 403 and 453 utilizes a plasma etch process. The formation results in a first (shallow) layer sidewall 415, a second (steep) layer sidewall 416, and a flat (non-sloped) surface 417 of the asymmetric graded dielectric layer 414, and a first (shallow) layer sidewall 465, a second (steep) layer sidewall 466, and a flat (non-sloped) surface 467 of the asymmetric graded dielectric layer 464. This transfer provides another opportunity to tune, smooth or round the staircase-like profile. In some examples, a flat etch front is utilized along with in-situ reflectometry for the etch endpoint. The dry etch may stop early, and finish with a hydrofluoric acid (HF) etch. In some examples, following the above-described tuning, smoothing, and/or rounding, the resulting sidewalls of the asymmetric graded dielectric layers 414 and 464 may retain, albeit reduced, some staircase-like or scalloped contour. FIG. 4K shows, in exploded view 470, a detailed view of a portion of the first (shallow) layer sidewall 465 of the asymmetric graded dielectric layer 464, illustrating how the staircase-like or scalloped contour of the nitride hard mask layer 454 is at least partially retained during the transfer of the profile utilizing the plasma etch process. The exploded view 470 of the first (shallow) layer sidewall 465 of the asymmetric graded dielectric layer 464 is also representative of the contour of the first (shallow) layer sidewall 415 of the asymmetric graded dielectric layer 414.

FIG. 4L shows a cross-sectional view of the structures of FIG. 4K following formation of gate electrodes 418 and 468. In some examples, depending on the material choice for the asymmetric graded dielectric layers 414 and 464, an additional oxide deposition may be performed prior to deposition of material (e.g., polysilicon, a metal, etc.) for the gate electrodes 418 and 468. Material for the gate electrodes 418 and 468 may be blanket deposited over the structure, followed by lithographic patterning to remove portions of the material to result in the gate electrodes 418 and 468 as shown in FIG. 4L. The gate electrodes 418 and 468 cover a portion of the asymmetric graded dielectric layers 414 and 464, as well as a portion of the epi layers 401 and 451 between the dashed lines 407 and 409, 408 and 410, 457 and 459, and 458 and 460.

In the process flow of FIGS. 4A-4L, overlapping the patterning masks (e.g., photoresist layers 406 and 456, drain patterning masks 413 and 463) for the shallow-sloped edge and the steep-sloped edge provides a method to scale the height of the asymmetric graded dielectric layers 414 and 464 for devices with different voltage characteristics. The slopes for the shallow-sloped and steep-sloped edges will be the same for different devices (e.g., for LV and HV devices), but the asymmetric graded dielectric layers 414 and 464 will vary by width and/or depth based on the amount of overlapping of the patterning masks. In some examples, however, respective shallow slopes and/or respective steep slopes for asymmetric graded dielectric layers may differ between devices. Thus, by way of example, lateral scaling between the asymmetric graded dielectric layers 414 and 464 is shown in FIG. 4K lateral dimension L1 of the asymmetric graded dielectric layer 414 is less than a lateral dimension L2 of the asymmetric graded dielectric layers 464. Further, by way of example, depth scaling between the asymmetric graded dielectric layers 414 and 464 is shown in FIG. 4K wherein a depth dimension D1 of the asymmetric graded dielectric layer 414 is less than a depth dimension D2 of the asymmetric graded dielectric layer 464. Still further, shallow slope dimension S1 is equal for both the asymmetric graded dielectric layers 414 and 464, as is the steep slope dimension S2.

Thus, by way of example, lateral scaling between asymmetric graded dielectric layers 414 and 464 is shown in FIG. 4K wherein a lateral dimension L1 of asymmetric graded dielectric layer 414 is less than a lateral dimension L2 of asymmetric graded dielectric layer 464. Further, by way of example, depth scaling between asymmetric graded dielectric layers 414 and 464 is shown in FIG. 4K wherein a depth dimension D1 of asymmetric graded dielectric layer 414 is less than a depth dimension D2 of asymmetric graded dielectric layer 464. Still further, shallow slope dimension S1 is equal for both asymmetric graded dielectric layers 414 and 464 as is steep slope dimension S2. In some examples, there may be about 14 nm alignment capability when using 248 nm lithographic processing.

FIG. 5A shows a cross-sectional view of a structure 500 including a semiconductor layer 501, a padding layer 502 that is blanket deposited over the semiconductor layer 501, insulating material 503 that is blanket deposited over the padding layer 502, and a photoresist layer 504 that is blanket deposited over the insulating material 503. The semiconductor layer 501 may be formed of silicon (Si) or another suitable semiconductor material. In some examples, the semiconductor layer 501 is formed using an epitaxial growth process and is thus referred to as epitaxial or “epi” layer 501. The padding layer 502 may be an oxide material with a thickness similar to that of the padding layers 402 and 452. The insulating material 503 will be used for forming an asymmetric graded dielectric layer. FIG. 5A also shows dashed lines 507, 509 and 511. Dashed line 507 illustrates where the source-side edge of the asymmetric graded dielectric layer will be formed, the dashed line 509 illustrates where the drain-side edge of the asymmetric graded dielectric layer will be formed, and the dashed line 511 illustrates where the sloped sidewalls of the asymmetric graded dielectric layer (e.g., the shallow-sloped sidewall that extends toward a source region and the steep-sloped sidewall that extends toward a drain region) will meet.

FIG. 5B shows a cross-sectional view where the structure 500 is subject to grayscale mask-based lithographic processing using a mask device 520. As shown, the mask device 520 is placed over the structure 500, and includes a light-passing substrate 513 with a first non-modulating region 515, a modulating region 517 and a second non-modulating region 519 formed on the light-passing substrate 513. A light source 521 is positioned over the mask device 520. The first non-modulating region 515 and the second non-modulating region 519 are areas where the photoresist layer 504 will be completely removed. The modulating region 517 includes a set of features, where at least a subset of the set of features are disposed at differing distances from one another for defining the shallow-sloped and steep-sloped sidewalls as defined by the dashed lines 507, 509 and 511. In examples where there is a non-sloped or flat portion between the shallow-sloped and steep-sloped sidewalls, this may also be defined utilizing the modulating region 517 or based on another non-modulating region (not expressly shown) appropriate positioned between the dashed lines 507 and 509.

FIG. 5C shows a cross-sectional view of the structure 500 following the grayscale mask-based lithographic process, where the photoresist layer 504 is patterned to have the desired shape for an asymmetric graded dielectric layer that is to be formed.

FIG. 5D shows a cross-sectional view of the structure 500 following transfer of the profile of the photoresist layer 504 into the underlying insulating material 503 forming asymmetric graded dielectric layer 522. The asymmetric graded dielectric layer 522 has a first (shallow) sidewall 523 with a slope dimension S1, a second (steep) sidewall 524 with a slope dimension S2, and a flat (non-sloped) surface 525.

The structures shown in FIGS. 4L and 5D may be subject to further processing to form LDMOS devices. Such additional processing includes forming source well regions, source regions, drain drift regions, drain regions, gate insulators, gates, silicide layers, an ILD, conductive vias, etc.

The processing steps for forming the asymmetric graded dielectric layers 414, 464 and 522 shown in FIGS. 4L and 5D (which may be referred to as an asymmetric graded dielectric process module hereinafter) may be integrated with other processing steps to form additional portions of an LDMOS device to result in one of the LDMOS devices 100 and 150 described above. In some examples, the asymmetric graded dielectric process module may be added prior to formation of processing steps for, e.g., forming a drain drift region (e.g., drain drift region 116 or drain drift region 166), forming a well region (e.g., well region 112 or well region 162), forming a gate insulator (e.g., gate insulator 118 or gate insulator 168), forming a gate electrode (e.g., gate electrode 122 or gate electrode 172), forming gate spacers (not specifically shown), forming a source region (e.g., source region 110 or source region 160) and a drain region (e.g., drain region 114 or drain region 164), forming silicide layers (e.g., silicide layers 124, 126 and 128 or silicide layers 174, 176 and 178), forming an ILD (e.g., ILD 130 or ILD 180) and forming conductive vias (e.g., conductive vias 132, 134 and 136 or conductive vias 182, 184 and 186).

In other examples, the asymmetric graded dielectric process module may be added after implants forming various drift and well regions in the semiconductor layer (e.g., epi layer 108 or epi layer 158), prior to forming a gate insulator (e.g., gate insulator 118 or gate insulator 168) and a gate electrode (e.g., gate electrode 122 or gate electrode 172) on the gate insulator. After forming the gate stack including the gate insulator and the gate electrode, additional process steps may be performed, e.g., forming gate spacers (not specifically shown), forming a source region (e.g., source region 110 or source region 160) and a drain region (e.g., drain region 114 or drain region 164), forming silicide layers (e.g., silicide layers 124, 126 and 128 or silicide layers 174, 176 and 178), forming an ILD (e.g., ILD 130 or ILD 180) and forming conductive vias (e.g., conductive vias 132, 134 and 136 or conductive vias 182, 184 and 186). Certain aspects of process flows for forming such additional portions will now be described.

In some examples, a drain drift region (e.g., drain drift region 116 or drain drift region 166) is formed in a semiconductor layer (e.g., epi layer 108 or epi layer 158) by performing one or more masked implantation steps, e.g., by forming a drain drift mask layer (or a photomask). In some examples, an implant to form the drain drift region occurs in two steps (e.g., a first implantation process with a first energy and a first dose followed by a second implantation process with a second energy and a second dose). In some examples, the first implantation process implants phosphorous dopants at the first energy of 20-40 kilo-electron volts (keV) and the first dose of 2-8×10¹² cm⁻². In some examples, the first implantation process implants phosphorus dopants at the first energy of 20-40 keV for an oxide thickness of 70-110 nm. In some examples, the first dose is 2-5×10¹² cm⁻². The second implantation process uses the same drain drift mask layer to implant the same region of the semiconductor layer. In some examples, the second energy is greater than the first energy. In some examples, the second implantation process implants phosphorus dopants at the second energy of 70-350 keV and the second dose of 2-5×10¹² cm⁻². In some examples, the second implantation process implants phosphorus dopants at the second energy less than or equal to 150 keV. In some examples, the second implantation process implants phosphorus dopants at the second energy greater than or equal to 100 keV, such as 100-350 keV. In some examples, the second implantation process includes more than one implant, such as an implantation at 120 keV and another implantation at 250 keV.

Following formation of the drain drift region, the drain drift mask layer is removed and a well region mask layer is patterned over the semiconductor layer to expose portions of the semiconductor layer where the well region (e.g., well region 112 or well region 162) is to be formed. An implantation process is then performed to implant p-type dopants within the exposed areas of the semiconductor layer to form the well region. The p-type dopants may include boron. Besides boron, the p-type dopants can include indium. Indium, being a relatively large atom, has the advantage of a low diffusion coefficient relative to boron. In the case of a boron implant, the implantation process uses a dose sufficient to enable formation of a channel laterally and to suppress body NPN effects during operation of an LDMOS device. For example, a boron implant with an energy of 20 keV, a dose of 8×10¹³ cm⁻² to 3.0×10¹⁴ cm⁻², such as 1.5×10¹⁴ cm⁻², and a tilt angle of less than 5 degrees, such as 2 degrees, may be used. The well region mask layer may then be removed after the implantation process.

The gate insulator (e.g., gate insulator 118 or gate insulator 168) and the gate electrode (e.g., gate electrode 122 or gate electrode 172) may be formed over the structure through deposition and patterning using one or more gate masking layers. In some examples, a gate insulator material is formed using a high temperature furnace operation or a rapid thermal process. The gate insulator material may have a thickness in the range of approximately 3 nm to 15 nm. Gate electrode material is then deposited over the gate insulator. In some examples, the gate electrode material is deposited using a gate deposition process using any of a number of silane-based precursors. Polycrystalline silicon is one example of a material for the gate electrode, however, a metal gate or a CMOS-based replacement gate process can also be used to form the gate electrode.

After deposition of the gate insulator material and the gate electrode material, a gate masking layer may be formed over the gate electrode material and the underlying gate insulator material where the final gate electrode and gate insulator should remain. Portions of the gate insulator material and the gate electrode material which are exposed by the one or more gate masking layers are then removed (e.g., using a plasma etch or other suitable etch process) to define the final gate electrode and gate insulator, and the one or more gate masking layers are then removed. In some examples, lightly doped drain regions are formed after patterning the gate electrodes, e.g., implanting n-type dopant species self-aligned at the edge of patterned gates. Subsequently, gate spacers may be formed on the sidewalls of the patterned gate electrodes.

In some examples, forming the gate spacers may be followed by formation of a source/drain mask layer that exposes portions of the well region (e.g., well region 112 or well region 162) and the drain drift region (e.g., drain drift region 116 or drain drift region 166) and the well region (e.g., well region 112 or well region 162) where the source region (e.g., source region 110 or source region 160) and the drain region (e.g., drain region 114 or drain region 164) are to be formed, respectively. An implantation process is then performed to implant n-type dopants within the exposed areas of the well region and the drain drift region to form the source region and the drain region. The source/drain mask layer is then removed.

After forming the source and drain regions, the silicide layers (e.g., silicide layers 124, 126 and 128 or silicide layers 174, 176 and 178) are then formed over the source region, the drain region and the gate electrode. In some examples, the silicide layers are formed by forming a metal layer, which forms a metal silicide at temperatures consistent with silicon processing conditions, followed by heating of the structure to form a metal silicide. Unreacted portions of the metal layer are then removed, such as using a wet stripping process.

The ILD (e.g., ILD 130 or ILD 180) is then deposited over the structure. The ILD is formed of a dielectric material. A contact masking layer is then formed over the ILD to expose regions of the ILD where the conductive vias (e.g., conductive vias 132, 134 and 136 or conductive vias 182, 184 and 186) are to be formed. Exposed regions of the ILD are then removed, followed by filling of the conductive vias, followed by removal of the contact masking layer. The conductive vias are formed of a suitable metal such as tungsten. Additional metal interconnects may be formed as desired to construct a metal interconnect system for the structure.

While FIGS. 4A-4L and 5A-5D respectively show process flows for formation of asymmetric graded dielectric layers prior to formation of a source region (e.g., source region 110 or source region 160), a well region (e.g., well region 112 or well region 162), a drain region (e.g., drain region 114 or drain region 164) and a drain drift region (e.g., drain drift region 116 or drain drift region 166), this is by way of example only. In other examples, the asymmetric graded dielectric layers may be formed subsequent to formation of a drain region, a drain drift region, a source region and a well region. Further, asymmetric graded dielectric layers may be formed using various other types of processing other than that shown in FIGS. 4A-5D.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a semiconductor layer;
a source region disposed in the semiconductor layer;
a drain region disposed in the semiconductor layer;
a gate electrode; and
an insulating layer disposed between a portion of the gate electrode and the semiconductor layer, the insulating layer having a first sidewall extending toward the source region and a second sidewall extending toward the drain region, the first sidewall having a first slope and the second sidewall having a second slope greater than the first slope.

2. The semiconductor device of claim 1, wherein the insulating layer comprises a dielectric material.

3. The semiconductor device of claim 2, wherein the dielectric material comprises an oxide material.

4. The semiconductor device of claim 2, wherein the dielectric material comprises a nitride material.

5. The semiconductor device of claim 1, wherein the first sidewall includes a first portion with the first slope and a second portion with a third slope less than the second slope.

6. The semiconductor device of claim 1, wherein the first slope comprises two or more component slopes including a first component slope between the source region and the drain region and at least a second component slope between the first component slope and the drain region, the first component slope being less than the second component slope.

7. The semiconductor device of claim 1, wherein at least a portion of the gate electrode extends past an edge of the insulating layer towards the source region.

8. The semiconductor device of claim 1, wherein a portion of the insulating layer extends past an edge of the gate electrode towards the drain region.

9. The semiconductor device of claim 1, wherein the first sidewall of the insulating layer comprises a scalloped contour.

10. The semiconductor device of claim 1, wherein the insulating layer further includes a non-sloped surface between the first sidewall and the second sidewall.

11. A semiconductor device, comprising:
a semiconductor layer;
a source region disposed in the semiconductor layer;
a drain region disposed in the semiconductor layer;
a gate electrode; and
an asymmetric graded field dielectric layer disposed between a portion of the gate electrode and the semiconductor layer, the asymmetric graded field dielectric layer having a first sloped section extending toward the source region and a second sloped section extending toward the drain region.

12. The semiconductor device of claim 11, wherein the first sloped section of the asymmetric graded field dielectric layer has a first width and the second sloped section of the asymmetric graded field dielectric layer has a second width less than the first width.

13. The semiconductor device of claim 11, wherein a first slope of the first sloped section of the asymmetric graded field dielectric layer is different than a second slope of the second sloped section of the asymmetric graded field dielectric layer.

14. The semiconductor device of claim 13, wherein the second slope is greater than the first slope.

15. A method of fabricating a semiconductor device, comprising:
forming an insulating layer over a semiconductor layer, the insulating layer having a first sidewall extending toward a first side and a second sidewall extending toward a second side opposite the first side, the first sidewall having a first slope and the second sidewall having a second slope greater than the first slope;
forming a gate electrode over at least a portion of the insulating layer;
forming a source region in the semiconductor layer, the source region spaced apart from the first side by the semiconductor layer; and
forming a drain region in the semiconductor layer, the drain region proximate to the second side.

16. The method of claim 15, wherein forming the insulating layer comprises:
forming an insulating material for the insulating layer over the semiconductor layer;
forming a hard mask layer over the insulating material;
forming a first patterning layer over a portion of the hard mask layer covering the drain region;
performing a partial etch of an exposed portion of the hard mask layer;
performing two or more iterations of (i) laterally trimming the first patterning layer to expose an additional portion of the hard mask layer and (ii) performing a partial etch of the exposed portions of the hard mask layer; and
removing the first patterning layer.

17. The method of claim 16, wherein forming the insulating layer further comprises:
forming a second patterning layer over a portion of the hard mask layer not covering the drain region;
etching an exposed portion of the hard mask layer;
removing the second patterning layer; and
transferring a pattern of the hard mask layer to the insulating material.

18. The method of claim 17, wherein at least one of the first patterning layer and the second patterning layer comprises a photoresist material.

19. The method of claim 15, wherein forming the insulating layer comprises:
forming an insulating material for the insulating layer over the semiconductor layer;
forming a photoresist layer over the insulating material;
generating a pattern in the photoresist layer utilizing a mask device comprising a light-passing substrate and a patterned opaque layer disposed on the light-passing substrate, the patterned opaque layer comprising a light modulating region for defining the first slope of the first sidewall and the second slope of the second sidewall; and
transferring the pattern of the photoresist layer to the insulating material.

20. The method of claim 19, wherein the light modulating region comprises a set of features, wherein at least a subset of the set of features are disposed at differing distances from one another for defining at least one of the first slope of the first sidewall and the second slope of the second sidewall.
